(19) United States
(12) Patent Application Publication
(10) Pub. No.: US 2008/0191273 A1
(43) Pub. Date: Aug. 14, 2008

(54) MOSFET DEVICE HAVING IMPROVED AVALANCHE CAPABILITY

(76) Inventors: Timothy Henson, Torrance, CA (US); Dev Alok Girdhar, Melbourne, FL (US)

Correspondence Address: OSTROLENK FABER GERB & SOFFEN, 1180 AVENUE OF THE AMERICAS, NEW YORK, NY, 100368403, US

(21) Appl. No.: 12/028,101

(22) Filed: Feb. 8, 2008

Related U.S. Application Data
(60) Provisional application No. 60/900,222, filed on Feb. 8, 2007.

(51) Int. Cl. H01L 29/78

(52) U.S. Cl. 257/331; 257/E29.262

(57) ABSTRACT

A power MOSFET that includes deep source field electrodes, the power MOSFET including one trench that includes an insulated gate and another trench that does not include an insulated gate, both trenches including a source field electrode, a source region adjacent the one trench and no source region adjacent the another trench, and a high conductivity contact region between the two trenches and disposed to divert at least a portion of the avalanche current away from regions under the source region and toward the high conductivity contact region.

### RELATED APPLICATION

This application is based on and claims priority to the U.S. Provisional Application Ser. No. 60/900,222, filed on Feb. 8, 2007, entitled MOSFET Device Having Improved Avalanche Capability, to which a claim of priority is hereby made and the disclosure of which is incorporated by reference.

### BACKGROUND AND SUMMARY OF THE INVENTION

U.S. patent application published as U.S. Patent Publication No. 2006/0033154 and U.S. patent application Ser. No. 11/890,849, both assigned to the assignee of the present application and incorporated by reference, disclose semiconductor power devices having deep source field electrodes that can exhibit lower Rdson.

In some applications, another figure of merit for a power MOSFET is avalanche robustness, which is the ability of a power MOSFET to withstand a higher current level during an unclamped inductive switching transient.

An object of the present invention is to improve the avalanche capability of the deep source electrode MOSFETs.

Thus, according to the present invention a MOSFET that includes deep source field electrodes is configured so that a portion of avalanche current therein is diverted away from regions under the source regions thereof and toward the contact between the source contact and the high conductivity contact regions thereof. Specifically, in a device according to the present invention the distance between the high conductivity contact regions and the gate trenches are reduced in order to divert avalanche current according to the present invention.

Other features and advantages of the present invention will become apparent from the following description of the invention which refers to the accompanying drawings.

### BRIEF DESCRIPTION OF THE DRAWINGS

FIG. 1 illustrates a cross-sectional view of the active region of a device according to the prior art.

FIG. 2 illustrates a cross-sectional view of an embodiment of the present invention.

FIG. 3 illustrates a cross-sectional view of another embodiment of the present invention.

### DETAILED DESCRIPTION OF EMBODIMENTS OF THE INVENTION

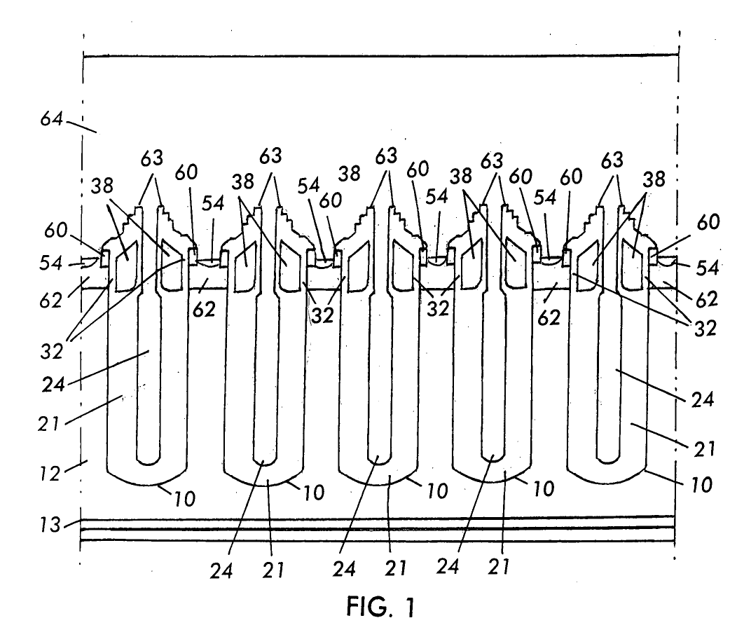

Referring to FIG. 1, a semiconductor device according to prior art is a power MOSFET that includes a plurality of spaced deep source trenches 10 formed in a semiconductor body 12, which can be an epitaxially grown silicon body of one conductivity (e.g. N type) disposed over a silicon substrate 13 of the same conductivity. Each trench 10 includes a thick oxide body 21 disposed in the interior and lining at least the bottom and a portion of the sidewalls thereof. The device of FIG. 1 includes channel regions 62 of the opposite conductivity to body 12 (e.g. P type), and source regions 60 of the same conductivity as body 12 formed in channel regions 62, and a plurality of insulated gate electrodes 38. Each gate electrode 38 is insulated from a respective channel region 62 by a gate oxide body 32, which is thinner than thick oxide body 21 disposed in trenches 10 and insulated from source electrode 64 by a top insulation body 63 (e.g. SiO₂). Furthermore each trench includes a deep source field electrode 24 formed with conductive polysilicon or the like which is insulated from gate electrodes 38 by intervening oxide layers, but extends through gate electrodes 38 contained therein. Deep source field electrodes 24 are ohmically coupled to a source contact 64, which is also ohmically coupled to source regions 60, and to channel regions 62 through a high conductivity contact region 54 (e.g. P+ conductivity) of the same conductivity as channel regions 62.

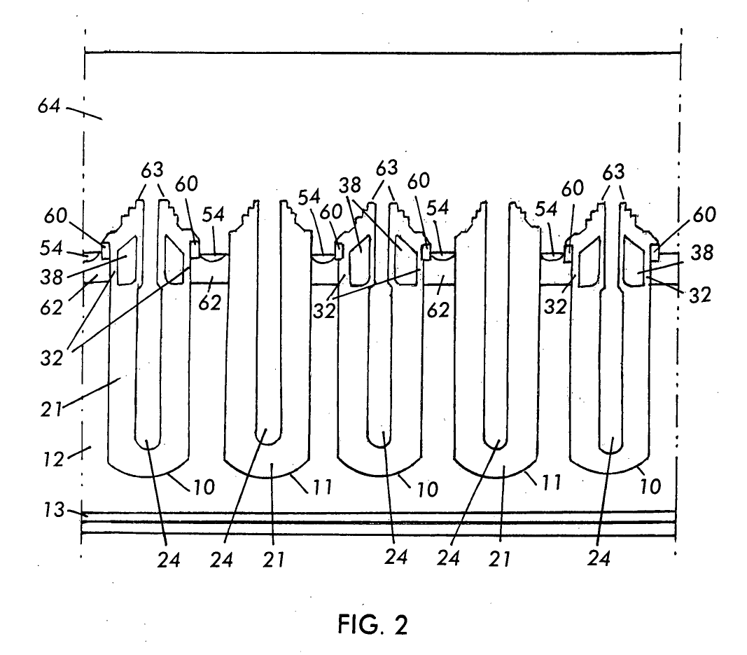

Referring now to FIG. 2, in which like numerals identify like features, a power MOSFET according to one embodiment of the present invention includes trenches 11, which extend to the same depth as trenches 10. Each trench 11 includes thick oxide body 21 along the sidewalls and the bottom thereof, and a deep source electrode 24 (formed with a conductive material such as conductive polysilicon) disposed therein adjacent thick oxide body 21. Preferably, trenches 10, 11 are alternately arranged; i.e. trench 10, trench 11, trench 10 and so forth. Trenches 11, unlike trenches 10, do not include insulated gate electrodes therein, and preferably no source regions 60 are formed adjacent trenches 11. Source field electrodes 24 in trenches 11 are directly connected to source contact 64. Note that each high conductivity contact region 54 is adjacent a portion of a respective sidewall of a trench 11. Further note that each mesa between two opposing trenches 10, 11 is adjacent only one insulated gate, namely the insulated gate within trench 10.

According to one aspect of the present invention, a power MOSFET according to the present invention is configured such that each high conductivity contact region 54 is brought closer to a sidewall of a trench 10 so that at least a portion of the avalanche current flows directly to and is collected by the contact between high conductivity contact region 54 and source contact 64 and does not flow under source region 60. Thus, the width of the mesa between trenches 10, 11 and the width of source region 60 in the mesa are selected in order to divert current to the contact between source contact 64 and high conductivity contact regions 54 and away from the regions under source region 60 in the mesa. As a result, the directed current will not be involved in triggering the parasitic bipolar transistor, thereby improving the avalanche capability of the device.

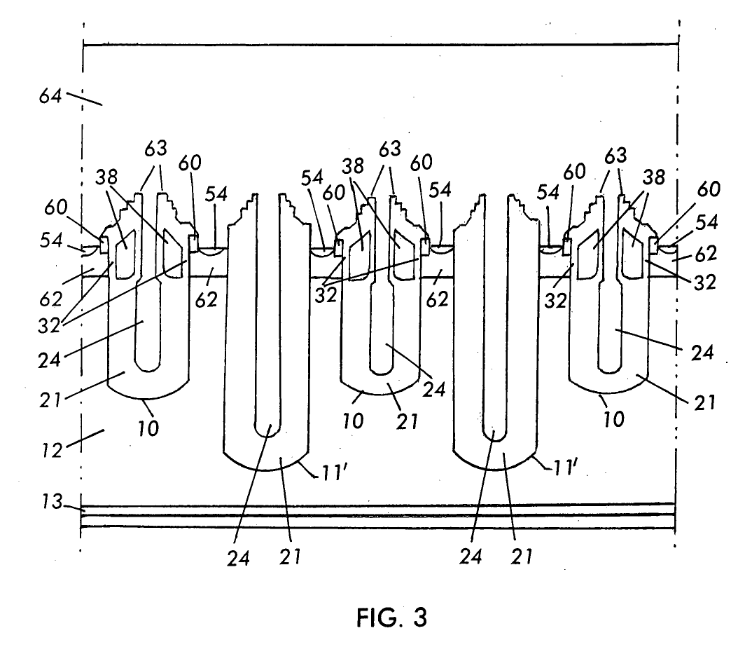

Referring now to FIG. 3, in which like numerals identify like features, in a MOSFET according to another embodiment of the present invention, trenches 11 are formed deeper than trenches 10. All other features are the same as those included in the first embodiment and described above.

According to one aspect of the second embodiment, more avalanche current is generated at trenches 11, and thus more current flows directly into the contact between high conductivity contact regions 54 and source contact 64, and less under source regions 60. As a result, the avalanche capability of the device is improved.

In addition to the above embodiments, other techniques can be used to direct avalanche current to the contact between source contact 64 and high conductivity contact regions 54, and away from regions under source regions 60. For example, thickness of oxide 21 or deep source electrodes 24 can be varied to obtain a device that diverts avalanche current according to the present invention.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A power semiconductor device comprising:
a semiconductor body of one conductivity, and a base region of another conductivity, said semiconductor body including a first surface;
a first trench extending from said first surface through said base region, said trench including at least two opposing sidewalls and a bottom;
a first gate insulation adjacent one of said sidewalls;
a first gate electrode adjacent said first gate insulation and spanning said base region;
a second gate insulation adjacent the other of said sidewalls;
a second gate electrode adjacent said second gate insulation and spanning said base region;
a source field electrode having a first portion and a second portion, said first portion of said source field electrode being disposed between said first and said second gate electrodes, and said second portion of said source field electrode being disposed below said first portion and said gate electrodes;
a source region adjacent each sidewall of said first trench;
a second trench not including a gate electrode spaced from said first trench opposite a source region and extending through said base region, said second trench including an insulation body disposed adjacent the sidewalls and the bottom thereof, and a source field electrode therein adjacent said insulation body;
a high conductivity contact region inside said base region, disposed between said first trench and said second trench; and
a source contact electrically connected to said source field electrodes in said first and said second trenches, said source regions, and said high conductivity contact region, wherein a distance between said high conductivity contact region and said first trench is selected to divert at least a portion of avalanche current to the contact between said source contact and said high conductivity contact region and away from regions under said source region opposite said second trench, and wherein no source region is disposed adjacent said second trench.

2. The device of claim 1, wherein said second trench extends deeper than said first trench.

3. The device of claim 1, further comprising a third trench not including a gate electrode spaced from said first trench opposite a source region and extending through said base region, said third trench including an insulation body disposed adjacent the sidewalls and the bottom thereof, and a source field electrode therein adjacent said insulation body; and
a high conductivity contact region inside said base region, disposed between said first trench and said third trench, said source contact being electrically connected to said source field electrode in said third trench, said source region, and said high conductivity contact region between said first trench and said third trench, wherein a distance between said high conductivity contact region and said first trench is selected to divert at least a portion of avalanche current to the contact between said source contact and said high conductivity contact region and away from regions under said source region opposite said third trench, and wherein no source region is disposed adjacent said third trench.

4. The device of claim 3, wherein said third trench extends deeper than said first trench.

5. The device of claim 3, wherein said second and third trenches extend deeper than said first trench.

6. The device of claim 1, wherein said source field electrodes are comprised of conductive polysilicon.
